(19) United States
(12) Patent Application Publication
(10) Pub. No.: US 2022/0308288 A1
(43) Pub. Date: Sep. 29, 2022

(54) METHOD FOR PACKAGING SEMICONDUCTOR STRUCTURE, PACKAGING STRUCTURE, AND CHIP

(71) Applicant: Institute of Microelectronics, Chinese Academy of Sciences, Beijing (CN)

(72) Inventors: Bo Tang, Beijing (CN); Yan Yang, Beijng (CN); Peng Zhang, Beijing (CN); Zhihua Li, Beijing (CN); Ruonan Liu, Beijing (CN); Fujun Sun, Beijing (CN); Kai Huang, Beijing (CN); Bin Li, Beijing (CN); Ling Xie, Beijing (CN); Wenwu Wang, Beijing (CN)

(21) Appl. No.: 17/294,645

(22) PCT Filed: Mar. 18, 2021
(86) PCT No.: PCT/CN2021/081449

§ 371 Date: May 17, 2021

(30) Foreign Application Priority Data
Sep. 30, 2020 (CN) 202011062486.3

(51) Int. Cl. G02B 6/132; H01L 21/02; H01L 21/768; H01L 23/48; H01L 25/16; H01L 27/12; G02B 6/30

(52) U.S. Cl. CPC G02B 6/132; H01L 21/02274; H01L 21/02164; H01L 21/0228; H01L 21/76898; H01L 23/481; H01L 25/167; H01L 27/1203; G02B 6/30; G02B 2006/12061

(57) ABSTRACT

A method for packaging a semiconductor structure, a packaging structure, and a chip. The method includes: forming the semiconductor structure on a SOI chip, where the semiconductor structure includes an edge coupler or a cavity structure; forming, through PECVD, silicon oxide on a surface of the semiconductor structure, where the surface is provided with an opening of a trench; and performing subsequent packaging. A characteristic of low step coverage of the PECVD is utilized for sealing an opening of a trench of the semiconductor structure, and addressed is an issue of a device failure due to the trench blocked by a packaging material in subsequent packaging.

The present application claims the priority to Chinese Patent Application No. 202011062486.3, titled “EDGE COUPLER, METHOD FOR PACKAGING THE SAME, AND APPLICATION OF THE SAME”, filed on Sep. 30, 2020 with the China National Intellectual Property Administration, which is incorporated herein by reference in its entirety.

### FIELD

The present disclosure relates to the technical field of photonic devices, and in particular to a method for packaging a semiconductor structure, a packaging structure, and a chip.

### BACKGROUND

Silicon photonics technology takes silicon as an optical medium and uses a CMOS (complementary metal oxide semiconductor) technique to develop and integrate optical devices. The silicon photonics technology is promising in realizing optical communication of a low cost and high speed, and has a broad prospect in market and application. Coupling between an optical fiber and a silicon photonic chip is a bottleneck hindering widespread application of the silicon photonic chips, and has to be addressed by any silicon photonic chip or any silicon photonic product. There are mainly two types of silicon waveguide couplers, namely, grating couplers and edge couplers. The grating coupler is advantageous in large alignment tolerance, easy packaging, a capability of on-chip testing, and the like, while it has low coupling efficiency and a narrow operation bandwidth. The edge coupler generally adopts a wedge-shaped structure, and is advantageous in high coupling efficiency and a large operation bandwidth.

At present, a process of manufacturing packaged silicon optical chips, of which the coupling is based on an edge coupler, includes a preceding process and post packaging. The preceding process is implemented by a preceding process line, which mainly refers to a CMOS production line. The post packaging is implemented by a post packaging line. Since heavy metals such as gold and copper are usually used in the post-packaging line, a wafer after the post packaging generally cannot be returned to the preceding process line for further processing. A problem in the post packaging is as follows. A chip with an edge coupler, which is manufactured by the preceding process line, is directly sent to the post packaging line when a silicon trench in a region of the edge coupler is exposed. In such case, the coupler would be filled with a packaging material (such as metal, silicon oxynitride, or another material with low refractive index) during packaging, resulting in malfunctions of the coupler. Embodiments of the present disclosure can be applied for addressing the packaging problem in a cavity structure.

In view of the above, solutions according to the present disclosure are proposed.

### SUMMARY

An object of embodiments of the present disclosure is to provide a method for packaging a semiconductor structure. The method utilizes a characteristic of low step coverage in plasma enhanced chemical vapor deposition (PECVD) when sealing an opening of a trench in the semiconductor structure, and thereby addresses an issue of a device failure due to a trench blocked by a packaging material in subsequent packaging.

In order to achieve the above object, technical solutions are provided according to embodiments of the present disclosure.

A method for packaging a semiconductor structure is provided, including:

forming the semiconductor structure on a silicon-on-insulator (SOI) chip, where the semiconductor structure includes an edge coupler or a cavity structure;

forming, through PECVD, silicon oxide on a surface of the semiconductor structure, where the surface is provided with an opening of a trench; and

performing subsequent packaging.

In an optional embodiment, a silicon source utilized in the PECVD is tetraethyl orthosilicate.

In an optional embodiment, the PECVD is performed under a deposition temperature of 400° C., a cavity pressure ranging from 6 Torr to 10 Torr, and a reflected power ranging from 600 W to 700 W.

In an optional embodiment, forming the semiconductor structure includes forming the trench into a silicon substrate.

In an optional embodiment, the subsequent packaging includes forming a through-silicon via (TSV), filling a seed layer, or copper electroplating.

In an optional embodiment, the SOI chip includes a buried oxide layer made of silicon oxide.

A packaging structure is further provided according to embodiments of the present disclosure, where the packaging structure is manufactured through the forgoing method.

A chip is further provided according to embodiments of the present disclosure, including the forgoing packaging structure. The chip is an optoelectronic chip that needs coupling to a light source or a chip including the cavity structure.

Compared with conventional technology, the solution in the present disclosure adds a process of depositing the silicon oxide through PECVD before a conventional process of packaging. Such additional process is capable to seal the opening of the trench in the semiconductor structure appropriately (rather than overfilling the trench), thereby avoiding a device failure due to a trench blocked by a packaging material in the subsequent packaging. Since PECVD has lower step coverage than other deposition processes such as LPCVD and ALD, i.e. the deposited film is less uniform, the deposited film of silicon oxide is thinner at the opening of the trench (than at the top surface of the semiconductor structure). Hence, the cavity in the trench can be retained to the most extent, and an adverse effect of sealing the opening on the trench is minimized. In comparison, when manufacturing other devices in this field, a deposited film (such as an insulating film, an electrode, a dielectric film, and the like) usually requires high step coverage. It can be seen that according to embodiments of the present disclosure, a disadvantage of PECVD is turned into an advantage and applied to the packaging of the semiconductor structure, and thereby packaging and integration are well balanced.

The packaging structure obtained through the foregoing method can be applied to the optoelectronic chip that needs coupling to the light source coupling or the chip including the cavity structure.

Embodiments of the present disclosure achieves following technical effects in comparison with conventional technology.

It is avoided that filling of a packaging material (such as metal, silicon oxynitride, or another material with low refractive index) blocks the trench of the edge coupler or the cavity structure, thereby improving device performances.

### BRIEF DESCRIPTION OF THE DRAWINGS

Other advantages and benefits would be apparent to those skilled in the art through reading detailed description of preferable embodiments as below. The drawings are only intended to illustrate the preferable embodiments, and are not considered as a limitation to the present disclosure.

FIG. 1 is a schematic structural diagram of a semiconductor structure according to an embodiment of the present disclosure;

FIG. 2 is a schematic diagram of sealed openings in an semiconductor structure as shown in FIG. 1 according to an embodiment of the present disclosure;

FIG. 3 is an electron microscope image of a semiconductor structure before sealing openings according to an embodiment of the present disclosure; and

FIG. 4 is an electron microscope image of a semiconductor structure after sealing openings according to an embodiment of the present disclosure.

### DETAILED DESCRIPTION OF EMBODIMENTS

Hereinafter embodiments of the present disclosure are described with reference to the drawings. It should be understood that these descriptions are only exemplary, and are not intended to limit the scope of the present disclosure. In addition, descriptions of well-known structures and technologies are omitted in the following illustration to avoid unnecessary obscureness of the concept of the present disclosure.

The drawings show various structural schematic diagrams according to embodiments of the present disclosure. These figures are not drawn to scale, and some details are enlarged while some details may be omitted for clarity of presentation. Shapes of the various regions and layers shown in the figure, as well as relative sizes and positional relationship between them, are only exemplary. In practice, there may be deviations due to manufacturing tolerances or technical limitations, and those skilled in the art may design areas/layers of different shapes, sizes, and relative positions according to a practical requirement.

In the context of the present disclosure, in a case that a layer/element is referred to as being “on” another layer/element, the layer/element may be directly on the other layer/element, or there may be an intermediate layer/element between the two. In addition, in a case a layer/element is located “on” another layer/element in an orientation, the layer/element may be located “under” the other layer/element when the orientation is reversed.

Manufacture of semiconductor structures include sequential processes of which the sequence cannot be reverted. In order to adapt to such characteristics and address an issue of a device failure due to a blocked trench, the present disclosure provides following implementations.

A method for packaging a semiconductor structure includes following steps.

The semiconductor structure is formed on a silicon-on-insulator (SOI) chip. The semiconductor structure includes an edge coupler or a cavity structure.

Silicon oxide is formed through plasma-enhanced chemical vapor deposition (PECVD) on a surface of the semiconductor structure. The surface is provided with an opening of a trench.

Subsequent packaging is performed.

Compared with conventional technology, the solution in the present disclosure adds a process of depositing the silicon oxide through PECVD before a conventional process of packaging. Such additional process is capable to seal the opening of the trench in the semiconductor structure appropriately (rather than overfilling), thereby avoiding a device failure due to a trench blocked by a packaging material in the subsequent packaging. Since PECVD has a lower step coverage than other deposition processes such as LPCVD and ALD, i.e. the deposited film is less uniform, the deposited film of silicon oxide is thinner at the opening of the trench (that at the top surface of the semiconductor structure). Hence, the cavity in the trench can be retained to the most extent, and an adverse effect of sealing the opening on the trench is minimized. In comparison, when manufacturing other devices in this field, a deposited film (such as an insulating film, an electrode, a dielectric film, and the like) usually requires high step coverage.

It can be seen that according to embodiments of the present disclosure, a disadvantage of PECVD is turned into an advantage and applied to the packaging of the semiconductor structure, and thereby packaging and integration are well balanced.

The trench herein mainly refers to a trench etched into a silicon substrate. Correspondingly, forming the semiconductor structure includes forming the trench into the silicon substrate.

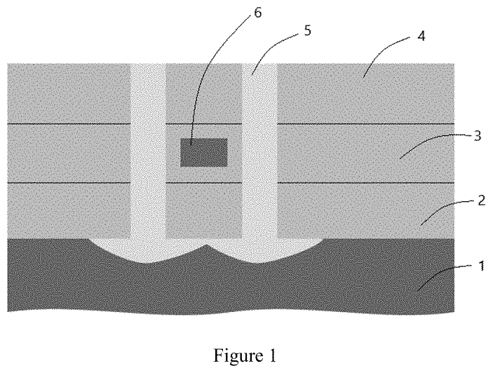

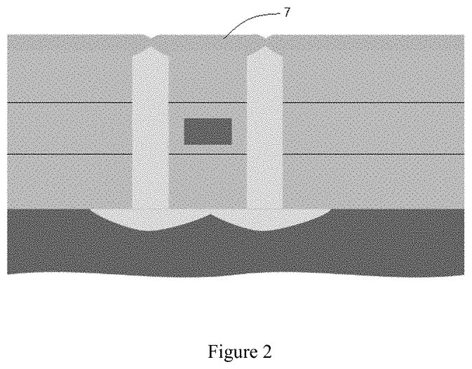

A shape of the trench is not limited herein. The trench includes, but is not limited to, a typical trench having a spheroid bottom. For example, the semiconductor structure is as shown in FIG. 1, and includes a silicon substrate 1, a buried oxide layer 2, top silicon 3, and a covering layer 4 made of silicon oxide according to a bottom-up sequence. A trench 5 running through extends into the silicon substrate 1, and a bottom of the trench 5 has a sphere-like shape. A rectangular waveguide 6 is formed in the top silicon. After openings are sealed according to embodiments of the present disclosure, a structure as shown in FIG. 2 is obtained. An uppermost layer is a film 7 made of silicon oxide, and a thickness of a top-layer portion of the film 7 is significantly greater than a thickness of a side-wall portion of the film 7.

In a preferable embodiment, the buried oxide layer of the SOI chip is made of silicon oxide.

In practice, the step coverage may be further reduced by adjusting a condition of the PECVD.

In a preferable embodiment, the PECVD are performed under the condition of: a deposition temperature of 400° C., a cavity pressure ranging from 6 Torr to 10 Torr, and a reflected power ranging from 600 W to 700 W.

Step coverage (SC)=(a thickness of a side-wall portion of a film/a thickness of a top-layer portion of the film)×100%

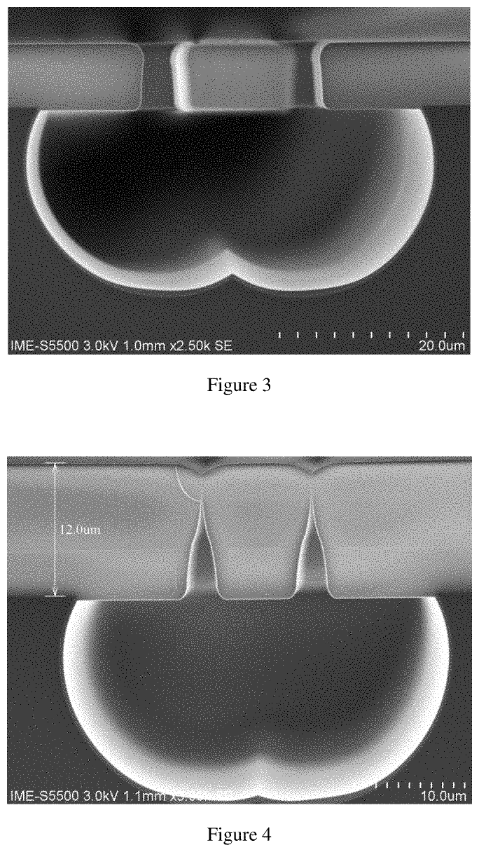

The semiconductor structure as shown in FIG. 1 is taken as an example. An electron microscope image of the semiconductor structure before the openings are sealed is as shown in FIG. 3, while an electron microscope image of the semiconductor structure after the openings are sealed is as shown in FIG. 4. In FIG. 4, the cavity at a bottom of the trench remains intact, and an adverse effect of sealing the openings is negligible to the device.

In a preferable embodiment, a thickness of the silicon oxide deposited through the PECVD is determined according to a following factor. The larger the opening is, the larger the thickness is to be deposited. The thickness to be deposited is approximately equal to a width of the opening.

A silicon source of the PECVD includes, but is not limited to, carbon-free precursors, such as silane (SiH₄), disilane (Si₂H₆), trisilane (Si₃H₈) and dichlorosilane (SiH₂Cl₂), and carbon-containing precursors, such as alkoxysilanes, alkylsilanes, cyclic siloxanes, alkynylsilanes, and orthosilicates (such as tetraethyl orthosilicate). Examples of suitable oxygen-containing reactants include O₂, CO₂, and N₂O. In a case that a silicon-containing precursor includes both silicon and oxygen (for example, tetraethyl orthosilicate), such single precursor can serves as both the silicon source and oxygen-containing reactant. Generally, gases for deposition, which contains the silicon-containing precursor and the oxygen-containing reactant, flow into a processing chamber along with a diluent gas (in some cases, a pre-vaporized liquid reactant is provided). Examples of the diluent gas include N₂ and rare gases, such as helium, argon, neon, or krypton.

In a preferable embodiment, a silicon source utilized in the PECVD is tetraethyl orthosilicate.

A flow and a condition for the subsequent packaging are not limited in embodiments of the present disclosure. The subsequent packaging includes, but is not limited to, a typical process of forming a through-silicon via (TSV), filling a seed layer, or copper electroplating.

The packaging structure obtained through any forgoing method can be applied to an optoelectronic chip that needs coupling to a light source or a chip including a cavity structure.

Hereinabove specific embodiments of the present disclosure are described. The embodiments are only intended for illustrating, rather than limiting the scope of the present disclosure. The scope of the present disclosure is defined by the appended claims and equivalents thereof. Those skilled in the art may make various replacements and modifications without deviating from the scope of the present disclosure, and these replacements and modifications should fall within the scope of the present disclosure.

1. A method for packaging a semiconductor structure, comprising:
forming the semiconductor structure on a silicon-on-insulator (SOI) chip, wherein the semiconductor structure comprises an edge coupler or a cavity structure;
forming, through plasma enhanced chemical vapor deposition (PECVD), a layer of silicon oxide on a surface of the semiconductor structure, wherein the surface is provided with an opening of a trench; and
packaging the semiconductor structure with the layer of silicon oxide.

2. The method according to claim 1, wherein a silicon source utilized in the PECVD is tetraethyl orthosilicate.

3. The method according to claim 1, the PECVD is performed under a deposition temperature of 400° C., a cavity pressure ranging from 6 Torr to 10 Torr, and a reflected power ranging from 600 W to 700 W.

4. The method according to claim 1, wherein forming the semiconductor structure comprises forming the trench into a silicon substrate.

5. The method according to claim 1, wherein the subsequent packaging comprises forming a through-silicon via (TSV), filling a seed layer, or copper electroplating.

6. The method according to claim 1, wherein the SOI chip comprises a buried oxide layer made of silicon oxide.

7. A packaged structure, manufactured through the method according to claim 1.

8. A chip, comprising the packaging structure according to claim 7, wherein: the chip is an optoelectronic chip that needs coupling to a light source or a chip comprising the cavity structure.

9. The method according to claim 2, the PECVD is performed under a deposition temperature of 400° C., a cavity pressure ranging from 6 Torr to 10 Torr, and a reflected power ranging from 600 W to 700 W.
